(19) United States
(12) Patent Application Publication
(10) Pub. No.: US 2025/0188617 A1
(43) Pub. Date: Jun. 12, 2025

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventors: Yuki TAIRA, Toyama-shi (JP); Akira HORII, Toyama-shi (JP); Kimihiko NAKATANI, Toyama-shi (JP)

(73) Assignee: KOKUSAI ELECTRIC CORPORATION, Tokyo (JP)

(21) Appl. No.: 19/058,598

(22) Filed: Feb. 20, 2025

Related U.S. Application Data
(63) Continuation of application No. PCT/JP2022/035986, filed on Sep. 27, 2022.

(51) Int. Cl. C23C 16/56; C23C 16/44; C23C 16/455; C23C 16/52

(52) U.S. Cl. CPC C23C 16/56; C23C 16/4408; C23C 16/4412; C23C 16/45534; C23C 16/45544; C23C 16/52

(57) ABSTRACT

A film forming step of forming a film on a substrate in a process chamber and a modifying step of modifying the film in the process chamber are included, and an exhaust amount discharged from the process chamber in the modifying step is made larger than an exhaust amount discharged from the process chamber in the film forming step.

### CROSS-REFERENCE TO RELATED APPLICATION

This application is a Bypass Continuation Application of PCT International Application No. PCT/JP2022/035986, filed on Sep. 27, 2022, the entire contents of which are incorporated herein by reference.

### BACKGROUND

### Field

The present disclosure relates to a method of processing a substrate, a method of manufacturing a semiconductor device, a substrate processing apparatus, and a recording medium.

### Description of the Related Art

Along with miniaturization and material change in recent LSI manufacturing steps, there is a need for a technique for forming a high-quality film at a low temperature. One means is to form a film on a substrate using an active species. This makes it possible to improve the film density and impurities in the film, but on the other hand, there is a disadvantage that the active species do not reach the entire substrate, and the in-plane uniformity of film thickness is deteriorated.

### SUMMARY

The present disclosure provides a technique capable of improving the in-plane uniformity of film thickness of a substrate.

According to one aspect of the present disclosure, there is provided a technique including: a film forming step of forming a film on a substrate in a process chamber; and a modifying step of modifying the film in the process chamber, in which an exhaust amount discharged from the process chamber in the modifying step is made larger than the exhaust amount discharged from the process chamber in the film forming step.

### BRIEF DESCRIPTION OF THE DRAWINGS

FIG. 1 is a schematic configuration diagram illustrating a substrate processing apparatus according to an embodiment of the present disclosure.

FIG. 2 is a cross-sectional view taken along line A-A of FIG. 1, illustrating the substrate processing apparatus according to the embodiment of the present disclosure.

FIG. 3 is a block diagram for explaining a controller included in the substrate processing apparatus according to the embodiment of the present disclosure.

FIG. 4 is a drawing illustrating a film formation sequence of a method of manufacturing a semiconductor device, according to the embodiment of the present disclosure.

FIG. 5 is a drawing illustrating operation timing of constituents in the film formation sequence of the method of manufacturing a semiconductor device, according to the embodiment of the present disclosure.

FIG. 6 is a diagram illustrating a configuration of an exhaust system according to the embodiment of the present disclosure.

FIG. 7 is a diagram illustrating a configuration of an exhaust system according to the embodiment of the present disclosure.

### DETAILED DESCRIPTION

Hereinafter, an example of the present embodiment will be described with reference to the drawings. In the drawings, the same or equivalent components and portions are denoted by the same reference numerals. In addition, dimensional ratios in the drawings are exaggerated for convenience of description, and may be different from actual ratios. In addition, description will be given assuming that an upward direction in the drawings is an upper side or an upper portion, and a downward direction in the drawings is a lower side or a lower portion. Furthermore, the pressures described in the present embodiment all mean atmospheric pressure. Note that an arrow UP illustrated in the drawing indicates the upper side of an apparatus.

### <General Structure of Substrate Processing Apparatus>

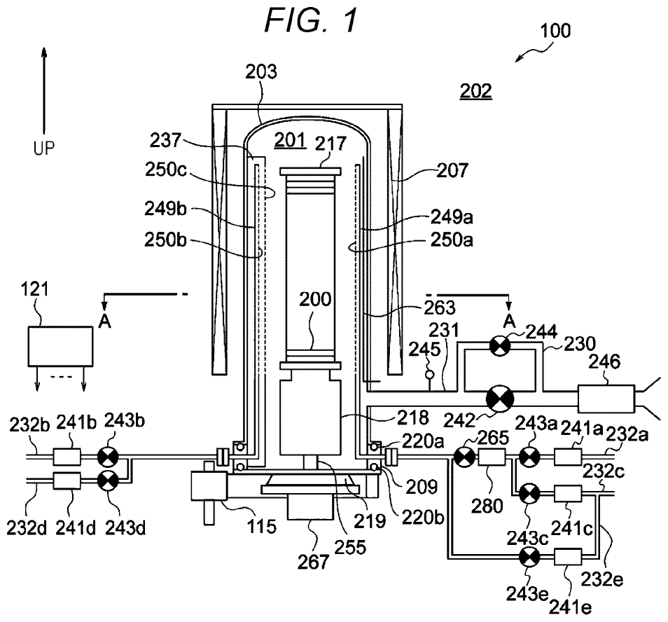

As illustrated in FIG. 1, a substrate processing apparatus 100 includes a process furnace 202, and a heater 207 serving as a heating means (heating mechanism) is disposed in the process furnace 202. The heater 207 has a cylindrical shape and is vertically installed by being supported by a heater base (not illustrated) serving as a holding plate.

Inside the heater 207, a reaction tube 203 is disposed concentrically with the heater 207. The reaction tube 203 is made of, for example, a heat-resistant material such as quartz (SiO2) or silicon carbide (SiC), and is formed in a cylindrical shape having the upper end closed and the lower end opened. A manifold (an inlet flange) 209 is disposed concentrically with the reaction tube 203 on the lower side of the reaction tube 203. The manifold 209 is made of, for example, a metal such as stainless steel (SUS) and is formed in a cylindrical shape in which the upper end and the lower end are open. The upper end portion of the manifold 209 engages with the lower end portion of the reaction tube 203 so as to support the reaction tube 203.

An O-ring 220a serving as a seal member is provided between the manifold 209 and the reaction tube 203. The manifold 209 is supported by the heater base, and thus, the reaction tube 203 is vertically installed. A process chamber 201 is formed in a cylindrical hollow portion of the reaction tube 203. The process chamber 201 is configured to be capable of accommodating wafers 200 serving as a plurality of substrates in a state where the wafers 200 are arranged in multiple stages in the vertical direction in a horizontal posture by a boat 217 described later.

In the process chamber 201, a nozzle 249a (a first nozzle) and a nozzle 249b (a second nozzle) extending in the up-down direction are provided so as to penetrate a side wall of the manifold 209. To the nozzles 249a and 249b, gas supply pipes 232a and 232b are connected, respectively. As a result, a plurality of types, here, two types of gases can be supplied into the process chamber 201.

In the gas supply pipes 232a and 232b, in order from the upstream side, mass flow controllers (MFC) 241a and 241b that are flow rate control devices (flow rate controllers) and valves 243a and 243b that are on-off valves are provided, respectively. Gas supply pipes 232c and 232d that supply inert gas are connected to the downstream sides of the valves 243a and 243b of the gas supply pipes 232a and 232b, respectively. In the gas supply pipes 232c and 232d, in order from the upstream side, MFCs 241c and 241d that are flow rate control devices (flow rate controllers) and valves 243c and 243d that are on-off valves are provided, respectively.

Furthermore, in the gas supply pipe 232a, on the downstream side of a connection portion to which the gas supply pipe 232c is connected, a storage (tank) 280 in which a source gas is stored and a valve 265 are provided in this order from the upstream side. In addition, on the downstream side of the valve 265 in the gas supply pipe 232a, a gas supply pipe 232e branching from the gas supply pipe 232c is connected. Furthermore, in the gas supply pipe 232e, an MFC 241e that is a flow rate control device (flow rate controller) and a valve 243e that is an on-off valve are provided in this order from the upstream side.

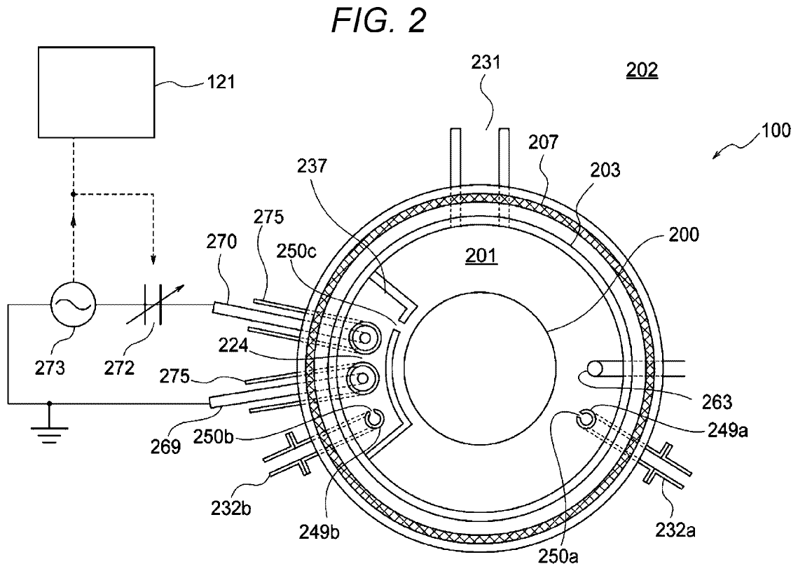

The nozzle 249a is connected to a tip portion of the gas supply pipe 232a. As illustrated in FIG. 2, the nozzle 249a is provided in an annular space between an inner wall of the reaction tube 203 and the wafers 200 so as to rise toward the upper side in the stacking direction (up-down direction) of the wafers 200 along the inner wall of the reaction tube 203 from the lower portion to the upper portion thereof. That is, the nozzle 249a is provided on a side of a wafer arrangement region where the wafers 200 are arranged.

The nozzle 249a is formed as an L-shaped long nozzle, a horizontal portion thereof is provided so as to penetrate the side wall of the manifold 209, and a vertical portion thereof is provided so as to rise at least from one end side toward the other end side of the wafer arrangement region. A gas supply hole 250a that supplies gas is provided on a side surface of the nozzle 249a. The gas supply hole 250a is opened to be directed toward the center of the reaction tube 203, and gas can be supplied toward the wafer 200. A plurality of the gas supply holes 250a is provided from the lower portion to the upper portion of the reaction tube 203, and the gas supply holes have the same opening area and are provided at the same opening pitch. The form of the nozzle 249a is not particularly limited, and for example, the horizontal portion and the vertical portion may be separate bodies.

The nozzle 249b is connected to a tip portion of the gas supply pipe 232b. The nozzle 249b is provided in a buffer chamber 237 serving as a gas dispersion space. As illustrated in FIG. 2, the buffer chamber 237 is provided in the annular space between the inner wall of the reaction tube 203 and the wafers 200 and in a portion extending from the lower portion to the upper portion in the process chamber 201 along the stacking direction of the wafers 200. That is, the buffer chamber 237 is provided in a region horizontally surrounding the wafer arrangement region on a side of the wafer arrangement region.

A gas supply hole 250c that supplies gas is provided at an end portion of a wall adjacent to the wafer 200 in the buffer chamber 237. The gas supply hole 250c is opened to be directed toward the center of the reaction tube 203, and gas can be supplied toward the wafer 200. A plurality of the gas supply holes 250c is provided from the lower portion to the upper portion of the reaction tube 203, and the gas supply holes have the same opening area and are provided at the same opening pitch.

The nozzle 249b is provided at an end portion of the buffer chamber 237 opposite to the end portion where the gas supply hole 250c is provided, so as to rise toward the upper side in the stacking (arrangement) direction of the wafers 200 along the inner wall of the reaction tube 203 from the lower portion to the upper portion thereof. That is, the nozzle 249b is provided on a side of the wafer arrangement region where the wafers 200 are arranged. The nozzle 249b is formed as an L-shaped long nozzle, a horizontal portion thereof is provided so as to penetrate the side wall of the manifold 209, and a vertical portion thereof is provided so as to rise at least from one end side toward the other end side of the wafer arrangement region. A gas supply hole 250b that supplies gas is provided on a side surface of the nozzle 249b. The gas supply hole 250b is opened so as to face the center of the buffer chamber 237. Similarly to the gas supply holes 250c, a plurality of the gas supply holes 250b is provided from the lower portion to the upper portion of the reaction tube 203. The form of the nozzle 249b is not limited similarly to the form of the nozzle 249a, and for example, the horizontal portion and the vertical portion may be separate bodies.

By adjusting the opening area and the opening pitch of the gas supply holes 250b from the upstream side to the downstream side as described above, it is possible to eject gas having substantially the same flow rate from each of the gas supply holes 250b although there is a difference in flow velocity. Then, by temporarily introducing the gas ejected from each of the plurality of gas supply holes 250b into the buffer chamber 237, it is possible to uniformize the flow velocity difference of the gas in the buffer chamber 237.

As described above, in the present embodiment, the gas is transferred via the nozzles 249a and 249b and the buffer chamber 237 disposed in an annular vertically long space defined by the inner wall of the reaction tube 203 and end portions of the plurality of wafers 200 stacked, that is, a cylindrical space.

Then, gas is ejected into the process chamber 201 for the first time in the vicinity of the wafer 200 from the gas supply holes 250a to 250c opened in the nozzles 249a and 249b and the buffer chamber 237, respectively. In addition, a main flow of the gas in the process chamber 201 is in a direction parallel to the surface of the wafer 200, that is, a horizontal direction. With such a configuration, gas can be uniformly supplied to the wafers 200, and the uniformity of film thickness of films to be formed on the wafers 200 can be improved. The gas that has flowed on the surface of the wafer 200, that is, the remaining gas after the reaction flows towards a direction of an exhaust port, that is, a second exhaust line 231 described later. However, the direction of the flow of the remaining gas is appropriately specified by the position of the exhaust port, and is not limited to the vertical direction.

As illustrated in FIG. 1, the source gas is supplied from the gas supply pipe 232a to the process chamber 201 through the MFC 241a, the valve 243a, the gas supply pipe 232a, the storage 280, the valve 265, and the nozzle 249a.

The source gas is a source in a gas state, for example, gas that is obtained by vaporizing a source in a liquid state under ordinary temperatures and pressures, a source that is in a gas state under ordinary temperatures and pressures, or the like. In the present specification, the term “source” may mean “liquid source in a liquid state”, “source gas in a gas state”, or both of them.

A reactant gas is supplied to the process chamber 201 from the gas supply pipe 232b, through the MFC 241b, the valve 243b, the gas supply pipe 232b, the nozzle 249b, and the buffer chamber 237.

In the present embodiment, a nitrogen (N₂) gas is supplied as an inert gas from the gas supply pipe 232c to the process chamber 201 through the MFC 241c, the valve 243c, the storage 280, the valve 265, and the gas supply pipe 232a.

In the present embodiment, a nitrogen (N₂) gas is supplied as an inert gas from the gas supply pipe 232e to the process chamber 201 through the MFC 241e, the valve 243e, and the gas supply pipe 232a.

In the present embodiment, a nitrogen (N₂) gas is supplied as an inert gas from the gas supply pipe 232d to the process chamber 201 through the MFC 241d, the valve 243d, the gas supply pipe 232b, and the buffer chamber 237.

In a case where the gas as described above is caused to flow from each gas supply pipe, mainly the gas supply pipe 232a, the MFC 241a, the valve 243a, the storage 280, and the valve 265 constitute a source gas supply system (source gas line) that supplies a source containing a predetermined element.

In addition, mainly the gas supply pipe 232b, the MFC 241b, and the valve 243b constitute a reactant gas supply system (reactant gas line) that supplies a reactant gas.

In addition, mainly the gas supply pipes 232c, 232d, and 232e, the MFCs 241c, 241d, and 241e, and the valves 243c, 243d, and 243e constitute an inert gas supply system.

In the buffer chamber 237, as illustrated in FIG. 2, two rod-shaped electrodes 269 and 270 made of a conductor and having an elongated structure are disposed along the stacking direction of the wafers 200 from the lower portion to the upper portion of the reaction tube 203. Each of the rod-shaped electrodes 269 and 270 is provided in parallel with the nozzle 249b. Each of the rod-shaped electrodes 269 and 270 is protected by being covered by an electrode protection tube 275 from the upper portion to the lower portion. One of the rod-shaped electrodes 269 and 270 is connected to a high-frequency power supply 273 through a matching device 272, and the other is connected to the ground as a reference potential. Radio frequency (RF) power is applied between the rod-shaped electrodes 269 and 270 from the high-frequency power supply 273 through the matching device 272, whereby plasma is generated in a plasma generation region 224 between the rod-shaped electrodes 269 and 270. Mainly the rod-shaped electrodes 269 and 270 and the electrode protection tube 275 constitute a plasma source serving as a plasma generating device (plasma generator). The plasma source functions as an activator (exciter) that activates (excites) a gas to a plasma state as described later.

As illustrated in FIG. 1, a first exhaust line 230 serving as a bypass exhaust line and the second exhaust line 231 serving as a main exhaust line are provided, which are exhaust pipes that exhaust an atmosphere of the process chamber 201. Specifically, the second exhaust line 231 serving as the exhaust pipe that exhausts the atmosphere of the process chamber 201 is connected to the reaction tube 203. One end of the second exhaust line 231 is connected to an exhaust port at the lower end portion of the process chamber 201. In addition, a vacuum pump 246 serving as an exhaust apparatus is connected to the second exhaust line 231 through a pressure sensor 245 serving as a pressure detecting device (pressure detector) that detects a pressure in the process chamber 201 and an auto pressure controller (APC) valve 242 serving as an on-off valve (pressure regulator). The APC valve 242 is a valve configured to be capable of exhausting and stopping exhausting the process chamber 201 by opening and closing the valve in a state where the vacuum pump 246 is operated, and further able to regulate the pressure of the process chamber 201 by adjusting a degree of valve opening on the basis of pressure information detected by the pressure sensor 245 in a state where the vacuum pump 246 is operated.

In addition, in the second exhaust line 231, the first exhaust line 230 is provided that branches upstream of the APC valve 242 and merges downstream of the APC valve 242. A flow path cross-sectional area of the first exhaust line 230 is made to be smaller than a flow path cross-sectional area of the second exhaust line 231. In other words, an exhaust amount of the second exhaust line 231 is made to be larger than an exhaust amount of the first exhaust line 230. In this case, since the vacuum pump 246 is common, the exhaust amount (exhaust capacity) of the second exhaust line 231 is made to be larger than the exhaust amount (exhaust capacity) of the first exhaust line 230. Thus, the exhaust amount (exhaust capacity) of each exhaust line can be regulated also by varying performance of the vacuum pump 246. Here, the first exhaust line 230 is provided with an auto pressure controller (APC) valve 244 serving as an on-off valve (pressure regulator). Mainly the first exhaust line 230, the second exhaust line 231, the APC valves 242 and 244, and the pressure sensor 245 constitute an exhaust system. The vacuum pump 246 may be included in the exhaust system.

A seal cap 219 serving as a furnace lid enabled to airtightly close a lower end opening of the manifold 209 is provided on the lower side of the manifold 209 as illustrated in FIG. 1. The seal cap 219 abuts against the lower end of the manifold 209 from the lower side in the vertical direction. The seal cap 219 is made of, for example, a metal such as SUS and is formed in a disk shape. On the upper surface of the seal cap 219, an O-ring 220b is provided serving as a seal member that is in contact with the lower end of the manifold 209. On an opposite side of the seal cap 219 from the process chamber 201, a rotation mechanism 267 is installed that rotates the boat 217 described later. A rotation shaft 255 of the rotation mechanism 267 penetrates the seal cap 219 and is connected to the boat 217. The rotation mechanism 267 is configured to rotate the wafer 200 by rotating the boat 217. The seal cap 219 is raised and lowered in the vertical direction by a boat elevator 115 as a serving raising/lowering mechanism vertically installed outside the reaction tube 203. The boat elevator 115 is configured to be capable of loading the boat 217 in the process chamber 201 and unloading the boat 217 from the process chamber 201 by raising and lowering the seal cap 219. The boat elevator 115 is configured as a transfer device (transfer mechanism) that transfers the boat 217 and the wafers 200 supported in the boat 217 to the inside and the outside of the process chamber 201.

The boat 217 serving as a substrate support tool is configured to support a plurality of, for example, 25 to 200 wafers 200 in the horizontal posture, in multiple stages so as to be aligned in the vertical direction with the centers aligned with one another, that is, the boat 217 is configured to arrange the wafers 200 at intervals. The boat 217 is made of a heat-resistant material such as quartz or Sic, for example. The lower portion of the boat 217 is provided with a heat insulation member 218 made of, for example, a heat-resistant material such as quartz or SiC.

The process chamber 201 is provided with a temperature sensor 263 serving as a temperature detector. A degree of energization to the heater 207 is regulated on the basis of temperature information detected by the temperature sensor 263, whereby temperature in the process chamber 201 has a desired temperature distribution. The temperature sensor 263 is formed in an L-shape similarly to the nozzles 249a and 249b, and is provided along the inner wall of the reaction tube 203.

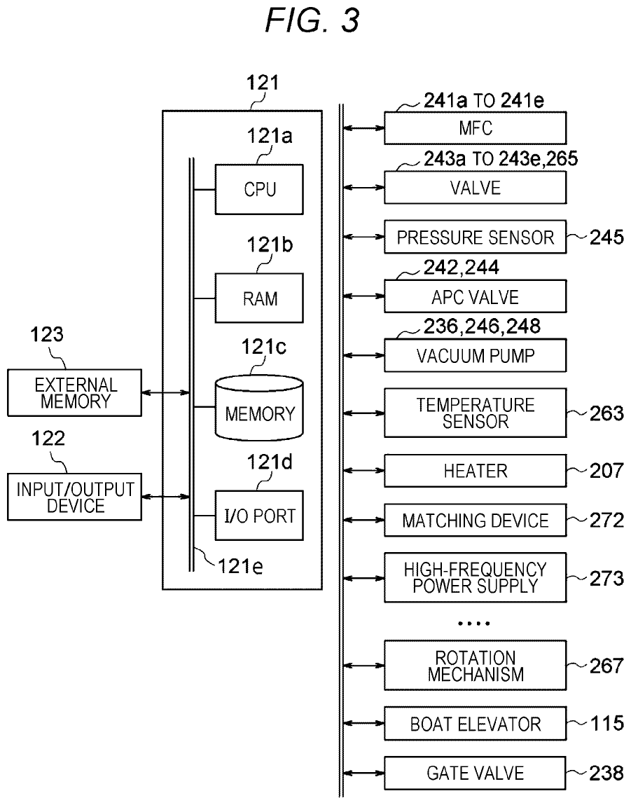

As illustrated in FIG. 3, a controller 121 as a controller (control means) is configured as a computer provided with a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a through an internal bus 121e. An input/output device 122 formed as, for example, a touch panel or the like is connected to the controller 121.

The memory 121c includes, for example, a flash memory, a hard disk drive (HDD), or the like. The memory 121c readably stores therein a control program that controls operation of the substrate processing apparatus, a process recipe in which procedures, conditions, and the like of substrate processing such as film forming described later are described, and the like. The process recipe is a combination of procedures in a substrate processing step such as the film forming step to be described later to cause the controller 121 to execute the procedures to obtain a predetermined result, and functions as a program. Hereinafter, the process recipe, the control program, and the like are also collectively and simply referred to as a program.

The I/O port 121d is connected to the above-described MFCs 241a to 241e, the valves 243a to 243e, and 265, the pressure sensor 245, the APC valves 242 and 244, the vacuum pump 246, the temperature sensor 263, the heater 207, the rotation mechanism 267, the boat elevator 115, the matching device 272, the high-frequency power supply 273, and the like.

The CPU 121a is configured to read the control program from the memory 121c and execute the control program, and read the process recipe from the memory 121c in response to an input of an operation command from the input/output device 122. The CPU121a is configured to control a flow rate regulation operation of various gases by the MFCs 241a to 241e, opening/closing operation of the valves 243a to 243e, and 265, pressure regulation operation by the APC valves 242 and 244 based on opening/closing operation of the APC valves 242 and 244 and the pressure sensor 245, a start and stop of the vacuum pump 246, temperature regulation operation of the heater 207 based on the temperature sensor 263, rotation and rotation speed adjustment operation of the boat 217 by the rotation mechanism 267, raising/lowering operation of the boat 217 by the boat elevator 115, impedance regulation operation by the matching device 272, power supply of the high-frequency power supply 273, and the like in accordance with contents of the read process recipe.

The controller 121 is not limited to being configured as a dedicated computer, and may be configured as a general-purpose computer. For example, the controller 121 of the present embodiment can be configured by preparing an external memory (for example, a magnetic tape, a magnetic disk such as a flexible disk or a hard disk, an optical disk such as a CD or a DVD, a magneto-optical disk such as an MO, or a semiconductor memory such as a USB memory or a memory card) 123 storing the above-described program, and installing the program in the general-purpose computer using the external memory 123. However, a means for supplying the program to the computer is not limited to a case of supplying the program through the external memory 123. For example, the program may be supplied using a communication means such as the Internet or a dedicated line without using the external memory 123. The memory 121c and the external memory 123 are configured as computer-readable recording media.

Hereinafter, the memories are also collectively and simply referred to as a recording medium. In a case where the term “recording medium” is used in the present specification, there is a case where only the memory 121c alone is included, a case where only the external memory 123 alone is included, or a case where both are included.

### (Film Forming Processing)

Next, as a step of a manufacturing step (manufacturing method) of a semiconductor device (semiconductor device) using the substrate processing apparatus 100 described above, a film formation sequence for formation of a film (film formation) on the wafer 200 will be specifically described with reference to FIGS. 1 to 5 as appropriate. In the following description, operation of constituents included in the substrate processing apparatus 100 is controlled by the controller 121.

### [Wafer Charge and Boat Load]

When the plurality of wafers 200 is charged into the boat 217 (wafer charge), as illustrated in FIG. 1, the boat 217 supporting the plurality of wafers 200 is lifted by the boat elevator 115 and loaded into the process chamber 201 (boat load). In this state, the seal cap 219 seals the lower end of the manifold 209 with the O-ring 220b interposed therebetween.

Note that, in the present specification, the term “wafer” may mean “a wafer itself” or “a laminate (assembly) of a wafer and a predetermined layer, film, or the like formed on a surface of the wafer”, that is, a wafer with a predetermined layer, film, or the like formed on a surface of the wafer may be referred to as a wafer. In addition, in the present specification, the term “surface of a wafer” may mean “a surface (exposed surface) of a wafer itself” or “a surface of a predetermined layer, film, or the like formed on a wafer, that is, an outermost surface of a wafer serving as a laminate”.

Thus, in the present specification, the description “supply a predetermined gas to a wafer” may mean “directly supply a predetermined gas to a surface (exposed surface) of a wafer itself” or “supply a predetermined gas to a layer, film, or the like formed on a wafer, that is, to an outermost surface of a wafer serving as a laminate”. In addition, in the present specification, the description “form a predetermined layer (or film) on a wafer” may mean “directly form a predetermined layer (or film) on a surface (exposed surface) of a wafer itself”, or “form a predetermined layer (or film) on a layer, film, or the like formed on a wafer, that is, on an outermost surface of a wafer serving as a laminate”.

### [Pressure Regulation and Temperature Regulation]

The vacuum pump 246 exhausts the gas (atmosphere) in the process chamber 201 so that the pressure in the process chamber 201, that is, the pressure in the space where there are the wafers 200, becomes a desired pressure (degree of vacuum). At this time, the pressure in the process chamber 201 is measured by the pressure sensor 245, and the APC valves 242 and 244 are feedback-controlled on the basis of the measured pressure information (pressure regulation). The vacuum pump 246 keeps operating at least until processing to the wafers 200 terminates.

The process chamber 201 is heated by the heater 207 so that the wafer 200 in the process chamber 201 reaches a desired processing temperature. At this time, the degree of energization to the heater 207 is feedback-controlled on the basis of the temperature information detected by the temperature sensor 263 so that the inside of the process chamber 201 has the desired temperature distribution (temperature regulation). The heater 207 keeps heating the process chamber 201 at least until processing to the wafers 200 terminates. However, in a case where processing is performed on the wafers 200 at room temperature, the process chamber 201 may not be heated by the heater 207.

Subsequently, the rotation mechanism 267 rotates the boat 217 and the wafers 200. The rotation mechanism 267 keeps rotating the boat 217 and the wafers 200 at least until processing to the wafers 200 terminates.

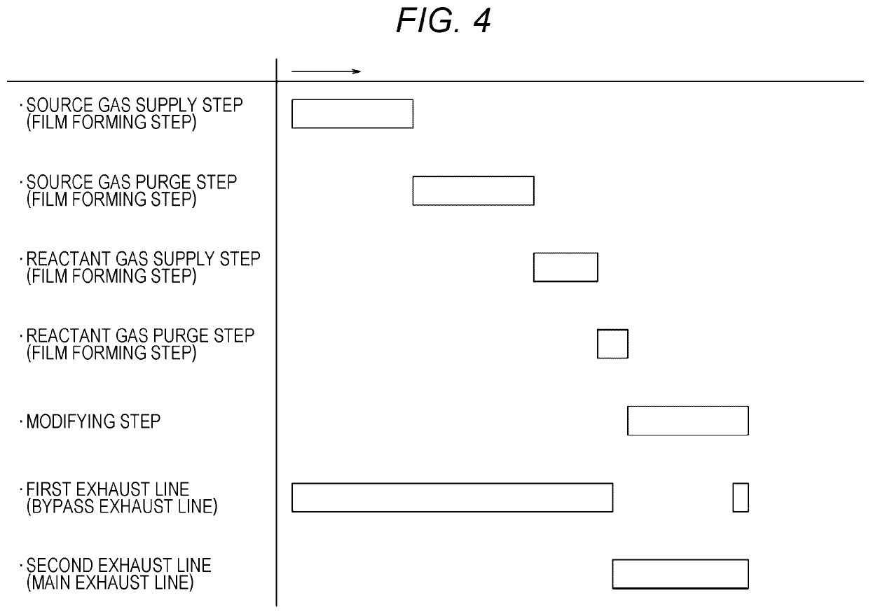

Then, the sequence illustrated in FIG. 4 is executed. Specifically, the film forming processing includes at least a film forming step and a modifying step. The film forming step includes at least a source gas supply step. The film forming step may include the source gas supply step and a reactant gas supply step. Furthermore, the film forming step may appropriately include a purge step as in the case of including the source gas supply step, a source gas purge step (a step of removing unreacted source gas, by-products, and the like in the process chamber 201 by exhausting the process chamber 201 or supplying N₂ gas to the process chamber 201), the reactant gas supply step, and a reactant gas purge step. In the modifying step, the film formed in the film forming step is modified. In this case, the film forming step and the modifying step may be set as one cycle, and each step may be repeatedly performed, or the film forming step may be performed a plurality of times and then the modifying step may be performed. In addition, the above-described purge step may be included between the film forming step and the modifying step.

### [Source Gas Supply Step (Film Forming Step)]

First, a step of supplying the source gas to the process chamber 201 will be described. Here, as an example, a description will be given of a method of storing the source gas in the storage 280 and then supplying the source gas. In the source gas supply step illustrated in FIG. 4, a step of supplying the N₂ gas to the process chamber 201, a step of supplying the N₂ gas to the process chamber 201 while supplying the source gas to the process chamber 201, and a step of supplying the N₂ gas to the process chamber 201 are sequentially performed. Specifically, in the first step of supplying the N₂ gas to the process chamber 201, the N₂ gas is supplied to the process chamber 201 at a first inert gas flow rate from the nozzle 249a extending in the up-down direction in a state where the exhaust of the process chamber 201 accommodating the wafers 200 is substantially stopped. Furthermore, in the step of supplying the N₂ gas to the process chamber 201 while supplying the source gas to the process chamber 201, the N₂ gas is supplied from the nozzle 249a to the process chamber 201 at a second inert gas flow rate larger than the first inert gas flow rate while supplying the source gas stored in the storage 280 from the nozzle 249a to the process chamber 201 in a state where the exhaust of the process chamber 201 is substantially stopped. In the next step of supplying the N₂ gas to the process chamber 201, the N₂ gas is supplied from the nozzle 249a to the process chamber 201 at the first inert gas flow rate in a state where the process chamber 201 is exhausted from the lower side. Here, the first exhaust line 230 is used for details of the exhaust in the step of supplying the source gas to the process chamber 201.

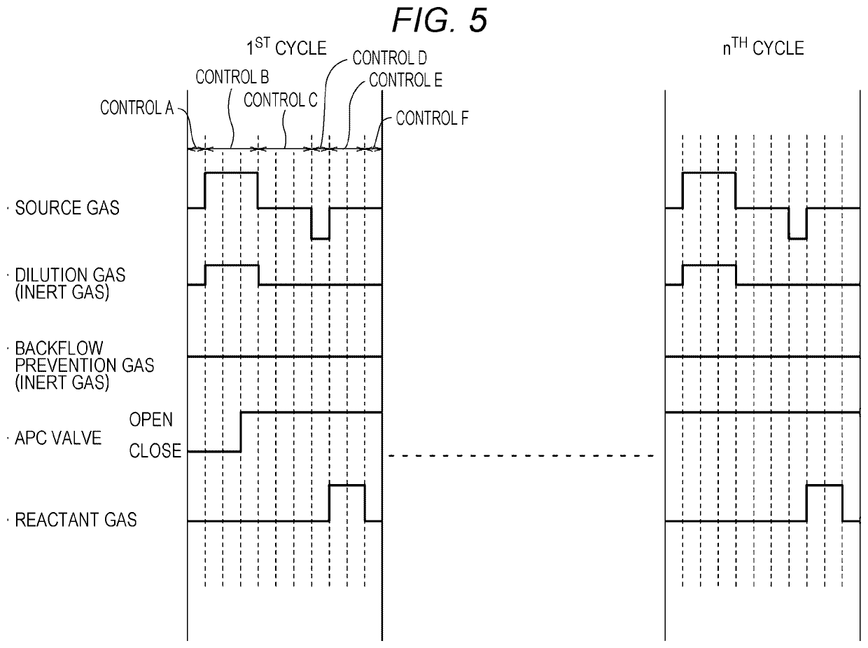

The N₂ gas is supplied to the process chamber 201 at the first inert gas flow rate from the nozzle 249a extending in the up-down direction in a state where the exhaust of the process chamber 201 accommodating the wafers 200 is substantially stopped. This step is performed, for example, for 1 second (1 s) in control A of the sequence illustrated in FIG. 5.

In this step, the valve 243a illustrated in FIG. 1 is opened, the valve 243b is closed, the valve 243c is closed, the valve 243d is opened, the valve 234e is opened, and the valve 265 is closed. Furthermore, the APC valves 242 and 244 are closed. The valve 243a is opened and the valve 265 is closed as described above, whereby the source gas is stored in the storage 280. Furthermore, the valve 243e is opened, whereby the N₂ gas is supplied from the nozzle 249a to the process chamber 201 at the first inert gas flow rate (for example, a predetermined value within a range of 0.5 to 3.0 [slm]). In addition, the valve 243d is opened, whereby the N₂ gas serving as a backflow prevention gas is supplied from the nozzle 249b to the process chamber 201 at a predetermined value within a flow rate range of 0.5 to 5.0 [slm], for example. Furthermore, the APC valves 242 and 244 are closed, whereby the exhaust of the process chamber 201 is substantially stopped. At this time, the temperature of the heater 207 is set so that the temperature of the wafers 200 is, for example, within a range of 300 to 600° C.

In this specification, an expression of a numerical range such as “300 to 600° C.” means that a lower limit value and an upper limit value are included in the range. Thus, for example, “300 to 600° C.” means “greater than or equal to 300° C. and less than or equal to 600° C.”. The same applies to other numerical ranges.

Here, a state where the exhaust of the process chamber 201 is substantially stopped is a state where the APC valves 242 and 244 serving as on-off valves are substantially closed and the exhaust of the 201 process chamber is substantially stopped. “Substantially” includes the following states. That is, a state is included where the APC valves 242 and 244 are fully closed (full close) and the exhaust of the process chamber 201 is stopped. In addition, “substantially” includes a state where the APC valves 242 and 244 are slightly opened to slightly exhaust the process chamber 201.

Here, in a state where the APC valves 242 and 244 are slightly opened and the process chamber 201 is slightly exhausted, it is preferable that an exhaust amount (exhaust rate) V [sccm] of the process chamber 201 per unit time is much smaller than a supply amount (supply rate) FB [sccm] of the N₂ gas per unit time, that is, FB>>V is satisfied. Specifically, the state where the APC valves 242 and 244 are slightly opened and the process chamber 201 is slightly exhausted includes a state where the supply amount FB of the N₂ gas per unit time is within +10% of the exhaust amount V of the process chamber 201 per unit time.

Note that, in the present step, gas is supplied in a state where the APC valves 242 and 244 are fully closed and the exhaust of the process chamber 201 is stopped.

In a state where the exhaust of the process chamber 201 is substantially stopped, the N₂ gas is supplied from the nozzle 249a to the process chamber 201 at the second inert gas flow rate larger than the first inert gas flow rate while the source gas stored in the storage 280 is supplied from the nozzle 249a to the process chamber 201. This step is performed, for example, for 3 seconds in control B of the sequence illustrated in FIG. 5.

In this step, the valve 243a is closed, the valve 243b is closed, the valve 243c is closed, the valve 243d is opened, the valve 243e is opened, and the valve 265 is opened. Furthermore, the APC valves 242 and 244 are closed. The valve 243a is closed and the valve 265 is opened as described above, whereby the source gas (for example, a predetermined amount within a range of 100-250 cc) stored in the storage 280 is supplied from the nozzle 249a to the process chamber 201 (so-called flash supply or flash flow). At this time, a large amount of the source gas is instantaneously supplied to the process chamber 201, and a small amount of the source gas is gradually supplied to the process chamber 201. The valve 243e is opened and the MFC 241e is controlled, whereby the N₂ gas is supplied from the nozzle 249a to the process chamber 201 at the second inert gas flow rate (for example, a predetermined value within a range of 1.5-4.5 [slm]) larger than the first inert gas flow rate. As a result, the source gas stored in the storage 280 is pushed out by the N₂ gas and supplied from the nozzle 249a to the process chamber 201. The valve 243d is opened, whereby the N₂ gas serving as the backflow prevention gas is supplied from the nozzle 249b to the process chamber 201 at a predetermined value within a flow rate range of 1.0-5.0 [slm], for example.

In this step of supplying the source gas, the APC valve 244 starts to be opened, and exhaust is started from the first exhaust line 230. For example, in FIG. 5, the APC valve 244 starts to be opened from around 4 [s].

### [Source Gas Purge Step (Film Forming Step)]

In the source gas purge step illustrated in FIG. 4, the N₂ gas is supplied from the nozzle 249a to the process chamber 201 at the first inert gas flow rate in a state where the process chamber 201 is exhausted. This step is performed for 3 seconds in control C of the sequence illustrated in FIG. 5.

In this purge step, the valve 243a is opened, the valve 243b is closed, the valve 243c is closed, the valve 243d is opened, the valve 243e is opened, and the valve 265 is closed. Furthermore, the APC valve 244 is opened to adjust the pressure of the process chamber 201 to a predetermined value within a range of 700 to 1200 [Pa], for example. The valve 243a is opened and the valve 265 is opened as described above, whereby the source gas starts to be stored in the storage 280 again. The valve 243e is opened and the MFC 241e is controlled, whereby the N₂ gas is supplied from the nozzle 249a to the process chamber 201 at the first inert gas flow rate (for example, a predetermined value within a range of 1.3 to 1.7 [slm]). The valve 243d is opened, whereby the N₂ gas serving as the backflow prevention gas is supplied from the nozzle 249b to the process chamber 201 at a predetermined value within a flow rate range of 1.3 to 1.7 [slm], for example. Note that, in the above description, the present step is performed by waiting for reaction of the source gas supplied to the process chamber 201 after performing the step of supplying the source gas to the process chamber 201 in a state where the valve 243a is closed; however, the present step may be performed by causing the source gas that has passed through the storage 280 to flow due to opening of the valve 243a. In that case, a flow rate of the source gas caused to flow in the step of supplying the source gas to the process chamber in a state where the valve 243a is closed may be referred to as a first source gas flow rate, and a flow rate of the source gas in the present step performed by causing the source gas that has passed through the storage 280 due to opening of the valve 243a to flow may be referred to as a second source gas flow rate (for example, a predetermined value within a range of 0.5 to 2.0 [slm]).

The source gas is supplied to the process chamber 201 as described above, whereby formation of a source-containing layer is started as a first layer on the wafer 200 (base film on the surface). The source-containing layer may be a layer, a source gas adsorption layer, or both of them may be included.

In addition, in the source gas purge step illustrated in FIG. 4, the source gas remaining in the process chamber 201 is removed, and the process chamber 201 is purged. In other words, this step is performed in control D of the sequence illustrated in FIG. 5.

In this step, the valve 243a is closed, the valve 243b is closed, the valve 243c is opened, the valve 243d is opened, the valve 243e is opened, and the valve 265 is opened. Furthermore, the APC valve 244 is opened. As a result, the valves 243c, 243e, and 267 are opened, whereby the N₂ gas is supplied from the nozzle 249a to the process chamber 201. The valve 243d is opened, whereby the N₂ gas is supplied from the nozzle 249b to the process chamber 201.

As described above, in the source gas purge step in which the source gas remaining in the process chamber 201 is removed, the APC valve 244 is opened, the gas in the process chamber 201 is exhausted by the vacuum pump 246, and the source gas remaining in the process chamber 201, which is unreacted or has contributed to the formation of the source-containing layer, is excluded from the process chamber 201 (residual gas removal). However, the APC valve 244 may not be fully opened as long as a sufficient exhaust amount can be obtained. At this time, the valves 243c and 243d are opened, and the supply of the N₂ gas to the process chamber 201 is maintained. The N₂ gas acts as a purge gas, whereby an effect is enhanced of excluding the source gas remaining in the process chamber 201, which is unreacted or has contributed to the formation of the source-containing layer, from the process chamber 201.

At this time, the gas remaining in the process chamber 201 may not be completely excluded, and the process chamber 201 may not be completely purged. If an amount of the gas remaining in the process chamber 201 is very small, no adverse effect occurs in a step to be performed thereafter. At this time, it is not necessary to set the flow rate of the N₂ gas supplied to the process chamber 201 to a large flow rate, and for example, by supply of an amount substantially equal to the volume of the process chamber 201, purge is performed to such an extent that no adverse effect occurs in a subsequent step. The process chamber 201 is not completely purged as described above, whereby the purge time is shortened and the throughput is improved. In addition, consumption of the N₂ gas can be minimized.

### [Reactant Gas Supply Step (Film Forming Step)]

In the reactant gas supply step illustrated in FIG. 4, the reactant gas is supplied from the nozzle 249b to the process chamber 201. This step is performed in control E of the sequence illustrated in FIG. 5.

In this step, the valve 243a is opened, the valve 243b is opened, the valve 243c is closed, the valve 243d is closed, the valve 243e is opened, and the valve 265 is closed. Furthermore, the APC valve 244 is opened. In addition, a voltage is applied between the rod-shaped electrodes 269 and 270. That is, the plasma-excited gas is supplied to the process chamber 201.

The valve 243a is opened and the valve 265 is closed as described above, whereby the source gas is stored in the storage 280. The valve 243e is opened, whereby the N₂ gas serving as the backflow prevention gas is supplied from the nozzle 249a to the process chamber 201. The valve 243b is opened, whereby the reactant gas is supplied from the nozzle 249b to the process chamber 201 at a predetermined value within a flow rate range of 0.5 to 10 [slm], for example. The APC valve 244 is opened, whereby the gas in the process chamber 201 is exhausted by the vacuum pump 246. At this time, the temperature of the heater 207 is set to a value similar to that at the time of supplying the source gas.

As a result, the reactant gas undergoes a surface reaction (chemical adsorption) with the source-containing layer formed on the surface of the wafer 200, and a desired film is formed on the wafer 200.

### [Reactant Gas Purge Step (Film Forming Step)]

In the reactant gas purge step illustrated in FIG. 4, the reactant gas remaining in the process chamber 201 is removed, and the process chamber 201 is purged. This step is performed in control F of the sequence illustrated in FIG. 5. The reactant gas purge step is an example of a first purge step or a second purge step.

In this step, the valve 243a is opened, the valve 243b is closed, the valve 243c is closed, the valve 243d is opened, the valve 243e is opened, and the valve 265 is closed. Furthermore, the APC valve 244 is opened. In addition, the voltage applied between the rod-shaped electrodes 269 and 270 is stopped.

The valve 243a is opened and the valve 265 is closed as described above, whereby the source gas is stored in the storage 280. The valve 243e is opened, whereby the N₂ gas is supplied from the nozzle 249a to the process chamber 201. The valve 243d is opened, whereby the N₂ gas is supplied from the nozzle 249b to the process chamber 201.

The above-described steps are set as one cycle, and the cycle is performed once or more (a predetermined number of times), whereby a film having a predetermined composition and a predetermined film thickness is formed on the wafer 200. It is preferable that a thickness of a layer formed per cycle is made smaller than a desired film thickness, and the above-described cycle is repeated a plurality of times until the desired film thickness is reached.

Processing of storing the source gas in the storage 280 due to opening of the valve 243a and closing of the valve 265 is continued until a predetermined amount is stored. For example, this processing may be continued up to the step of supplying the reactant gas from the nozzle 249b to the process chamber 201 and the step of removing the reactant gas remaining in the process chamber 201.

Then, in the reactant gas purge step (control F illustrated in FIG. 5) of removing the reactant gas remaining in the process chamber 201 immediately before transitioning to the modifying step next, switching of the exhaust line (exhaust system) is performed. Specifically, switching is performed from gas piping (first exhaust line 230) of an exhaust system used in supplying the source gas and the reactant gas (film forming step) to gas piping (second exhaust line 231) of an exhaust system used in a step in which the formed film is modified. As described above, the flow path cross-sectional area of the second exhaust line 231 is made to be larger than the flow path cross-sectional area of the first exhaust line 230. For example, the flow path cross-sectional area of the second exhaust line 231 is made to be twice or more the flow path cross-sectional area of the first exhaust line 230.

The APC valve 244 of the first exhaust line 230 illustrated in FIG. 1 is fully closed, and the APC valve 242 of the second exhaust line 231 is opened. For example, in the purge step immediately before transitioning to the modifying step, the valve 243a is opened, the valve 243b is closed, the valve 243c is closed, the valve 243d is opened, the valve 243e is opened, and the valve 265 is closed. Furthermore, the APC valve 242 of the second exhaust line is opened, and the step of removing the reactant gas is performed. In short, it is sufficient that exhaust by the second exhaust line is enabled before the modifying step.

### [Modifying Step]

Next, the modifying step illustrated in FIG. 4 will be described. In this modifying step, the film having the predetermined composition and the predetermined film thickness formed on the wafer 200 is modified.

In this step, the valve 243a is opened, the valve 243b is closed, the valve 243c is closed, the valve 243d is opened, the valve 243e is opened, and the valve 265 is closed. Furthermore, the APC valve 242 of the second exhaust line 231 is fully opened. In addition, a voltage is applied between the rod-shaped electrodes 269 and 270 illustrated in FIG. 2. That is, the plasma-excited inert gas is supplied to the process chamber 201.

The APC valve 242 of the second exhaust line 231 is opened, whereby the plasma-excited gas (active species) in the process chamber 201 is exhausted by the vacuum pump 246 through the second exhaust line 231.

As described above, in the film forming step in which a predetermined film is formed on the wafer 200, the exhaust is performed through the APC valve 244 of the first exhaust line 230, and in the modifying step in which the film is modified, the exhaust is performed through the APC valve 242 of the second exhaust line 231.

In the present embodiment described above, the film is formed on the wafer 200 while the exhaust is performed through the first exhaust line 230, and the wafer 200 is modified while the exhaust is performed through the second exhaust line 231 having a larger flow path cross-sectional area than the first exhaust line 230. That is, an exhaust amount of gas in the modifying step in which the film is modified is made to be larger than an exhaust amount of gas in the film forming step of forming the film on the wafer 200. As a result, even when a supply amount of a modifier is increased, a low pressure is maintained, and further, a processing pressure is reduced. Such a low pressure can, for example, improve a mean free path of the activated modifier and thus increase transport efficiency of the activated modifier.

In addition, due to reduction in pressure, the modifier that remains activated can be supplied to the surface of the wafer 200, and in particular, the modifier that remains activated can be spread over the central portion of the wafer 200. Thus, in the present embodiment, since the active species (activated modifier) spreads over the entire wafer 200, the in-plane uniformity of film thickness can be improved.

In addition, the exhaust amount of gas is increased, whereby it is possible to achieve reduction in pressure without decreasing the gas flow rate, and it is expected to achieve both the supply amount of the modifier and the life of the plasma-excited gas (active species).

In addition, since exhaust conductance can be lowered by switching from the first exhaust line 230 to the second exhaust line 231, the low pressure is maintained while the modifier or the active species is increased. Such a low pressure increases the transport efficiency of the modifier or active species. Thus, as described above, since the active species (activated modifier) spreads over the entire wafer 200, the in-plane uniformity of film thickness can be improved.

Here, an upper limit of the low pressure is determined by whether the in-plane uniformity is reduced due to that the active species cannot be supplied to the center of the wafer 200. Furthermore, a lower limit of the low pressure is determined by whether the in-plane uniformity is reduced due to that the mean free path is too large (no collision with the wafer 200 occurs) and thus no active species is generated, or even if an active species is generated, collision at the wafer periphery is reduced and an amount of active species generated is reduced.

In the present embodiment, switching to the second exhaust line 231 is performed to increase the exhaust amount of gas, whereby the supply of the modifier is achieved under a condition that the pressure falls within a range between the upper limit and the lower limit of the low pressure.

Note that, at this time, the temperature of the heater 207 may be set to a value similar to that at the time of supplying the source gas.

### [Purge and Return to Atmospheric Pressure]

After the film forming processing of forming the film having the predetermined composition and the predetermined film thickness is performed, the valves 243c, 243d, and 243e are opened, and the N₂ gas serving as the inert gas is supplied from each of the gas supply pipes 232c, 232d, and 232e to the process chamber 201 and exhausted from the second exhaust line 231. The N₂ gas acts as a purge gas, whereby the process chamber 201 is purged with the inert gas, and a gas remaining in the process chamber 201 and reaction by-products are removed from the process chamber 201 (purge). Thereafter, the atmosphere in the process chamber 201 is replaced with inert gas (inert gas replacement), so that the pressure of the process chamber 201 is returned to normal pressure (return to atmospheric pressure).

### [Boat Unload and Wafer Discharge]

Thereafter, the seal cap 219 is lowered by the boat elevator 115, the lower end of the manifold 209 is opened, and the processed wafers 200 are unloaded from the lower end of the manifold 209 to the outside of the reaction tube 203 in a state of being supported by the boat 217 (boat unload). Thereafter, the processed wafers 200 are taken out from the boat 217 (wafer discharge).

In the step of regulating the pressure described above, in a step of reducing the pressure from a pressure near the atmospheric pressure to a first pressure, the process chamber 201 may be exhausted using the first exhaust line 230, in a step of reducing the pressure from the first pressure to a second pressure, the second exhaust line 231 may be used, and in a step of changing the pressure from the second pressure to the processing pressure, the process chamber 201 may be exhausted using the first exhaust line 230. This makes it possible to shorten the time for reducing the pressure from the atmospheric pressure to the processing pressure. Although vacuum exhaust is performed in any of the steps described above, the purge gas may be supplied in the any of the steps.

### Modified Example 1

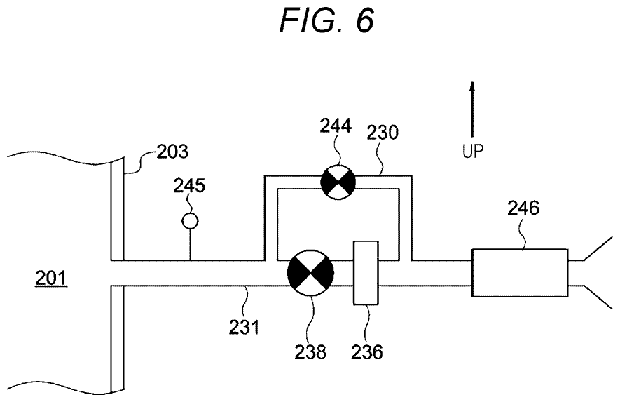

Next, Modified Example 1 will be described. As described above, it is sufficient that the exhaust amount in the film forming step can be increased in the modifying step, and thus, in Modified Example 1, as illustrated in FIG. 6, a gate valve 238 is provided instead of the APC valve in the second exhaust line 231.

Even in such a configuration, since the exhaust conductance can be lowered by switching from the first exhaust line 230 to the second exhaust line 231, the low pressure is maintained while the modifier or the active species is increased. Such a low pressure increases the transport efficiency of the modifier or active species. Thus, as described above, since the active species (activated modifier) spreads over the entire wafer 200, the in-plane uniformity of film thickness can be improved.

### Modified Example 2

Next, Modified Example 2 will be described. Modified Example 2 is an improved version of Modified Example 1. As illustrated in FIG. 6, the second exhaust line 231 is provided with the gate valve 238 instead of the APC valve, and further, in the second exhaust line 231, a vacuum pump 236 serving as an exhaust apparatus is provided downstream of the gate valve 238 and upstream of a merging portion with the first exhaust line 230. In this configuration, in a case where exhaust is performed through the gate valve 238, the vacuum pumps 236 and 246 operate.

In this configuration, in addition to the configuration of Modified Example 1, the vacuum pump 236 operates, whereby a reduction in pressure can be expected as compared with Modified Example 1. As a result, since the exhaust conductance can be lowered, the low pressure is maintained while the modifier or the active species is increased. Such a low pressure increases the transport efficiency of the modifier or active species. As described above, since the active species (activated modifier) spreads over the entire wafer 200, the in-plane uniformity of film thickness can be improved. However, in this case, there is a concern that the exhaust capacity of the vacuum pump 236 is increased and the pressure is excessively lowered. Then, the mean free path is too large (no collision with the wafer 200 occurs), and a phenomenon occurs in which an active species is not generated.

### Another Embodiment

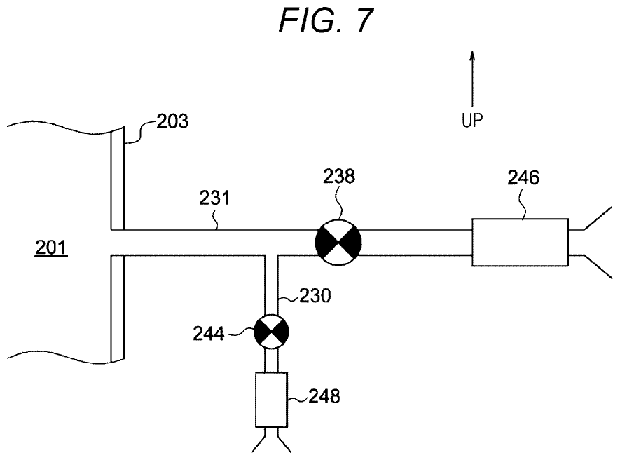

Next, another embodiment will be described. In another embodiment, as illustrated in FIG. 7, a vacuum pump serving as an exhaust apparatus is provided in each of the first exhaust line 230 and the second exhaust line 231.

Specifically, the second exhaust line 231 is provided with the gate valve 238. The first exhaust line 230 branches from the upstream side of the gate valve 238 in the second exhaust line 231, and does not merge with the second exhaust line 231.

The first exhaust line 230 is provided with the APC valve 244 and a vacuum pump 248 disposed downstream of the APC valve 244. The exhaust performance of the vacuum pump 248 is made weaker than the exhaust performance of the vacuum pump 246. In other words, the exhaust performance of the vacuum pump 246 is made stronger than the exhaust performance of the vacuum pump 248.

In this configuration, in the film forming step, the APC valve 244 of the first exhaust line 230 is opened, and the gate valve 238 of the second exhaust line 231 is closed. Furthermore, the vacuum pump 248 is operated. As a result, in the film forming step, exhaust is performed through the APC valve 244 of the first exhaust line 230.

In the modifying step, the APC valve 244 of the first exhaust line 230 is fully opened, and the gate valve 238 of the second exhaust line 231 is opened. Furthermore, the vacuum pumps 246 and 248 are operated. As a result, in the modifying step, exhaust is performed through the APC valve 244 of the first exhaust line 230, and further, exhaust is performed through the gate valve 238 of the second exhaust line 231. Alternatively, in the modifying step, the APC valve 244 of the first exhaust line 230 is closed, and the gate valve 238 of the second exhaust line 231 is opened. Furthermore, the vacuum pump 246 is operated. As a result, in the modifying step, exhaust is performed through the gate valve 238 of the second exhaust line 231.

Even in such a configuration, in comparison between the vacuum pump 248 provided in the first exhaust line and the vacuum pump 246 provided in the second exhaust line, since the exhaust capacity of the vacuum pump 246 is higher, the exhaust conductance can be lowered by switching from the first exhaust line 230 to the second exhaust line 231, so that the low pressure is maintained while the modifier or the active species is increased. Such a low pressure increases the transport efficiency of the modifier or active species. Thus, as described above, since the active species (activated modifier) spreads over the entire wafer 200, the in-plane uniformity of film thickness can be improved.

As described above, according to the present disclosure, the following one or more effects can be obtained.

According to one aspect of the present disclosure, the exhaust amount of gas in the modifying step is made larger than the exhaust amount of gas in the film forming step. The exhaust amount in the modifying step is increased as described above, whereby the low pressure can be maintained even when the supply amount of the modifier is increased, and further, the processing pressure can be reduced. Such a low pressure can increase the transport efficiency of the activated modifier. Thus, since the active species (activated modifier) spreads over the entire wafer 200, the in-plane uniformity of film thickness can be improved.

In addition, according to one aspect of the present disclosure, the active species in the modifying step is activated by heat. As a result, the film density and impurities in the film can be improved by use of the activated inert gas (modifier), so that a film having good film quality can be formed at a low temperature. Furthermore, by increasing the exhaust amount of gas in the modifying step, it is possible to achieve reduction in pressure without decreasing the amount of active species activated by heat, and by such reduction in pressure, it is possible to increase the transport efficiency of the active species activated by heat. Thus, since the active species (activated modifier) spreads over the entire wafer 200, the in-plane uniformity of film thickness can be improved.

In addition, according to one aspect of the present disclosure, the active species in the modifying step is plasma-excited. As a result, the film density and impurities in the film can be improved by use of the activated inert gas (modifier), so that a film having good film quality can be formed at a low temperature. Furthermore, by increasing the exhaust amount of gas in the modifying step, it is possible to achieve reduction in pressure without decreasing the amount of the plasma-excited active species, and by such reduction in pressure, it is possible to increase the transport efficiency of the plasma-excited active species. Thus, since the active species (activated modifier) spreads over the entire wafer 200, the in-plane uniformity of film thickness can be improved.

In addition, according to one aspect of the present disclosure, the film forming step and the modifying step are set as one cycle and executed a predetermined number of times or more, whereby a film having a predetermined film thickness can be formed. As a result, even in the case of a film having a predetermined film thickness, it is possible to achieve reduction in pressure without decreasing the amount of the modifier in the modifying step, and it can be expected to achieve both the supply amount of the modifier and the life of the active species. Furthermore, since the film density and impurities in the film can be improved by use of the active species, a film having good film quality can be formed at a low temperature.

In addition, the film forming step is executed a plurality of times and then the modifying step is executed, whereby a film having a predetermined film thickness can be formed. As a result, even in the case of a film having a predetermined film thickness, it is possible to achieve reduction in pressure without decreasing the amount of the modifier in the modifying step, and it can be expected to achieve both the supply amount of the modifier and the life of the active species. Furthermore, since the film density and impurities in the film can be improved by use of the active species, a film having good film quality can be formed at a low temperature.

In addition, a configuration is made including the first exhaust line 230 configured to exhaust gas from the process chamber 201 in which the wafer 200 is processed, and the second exhaust line 231 configured to have the flow path cross-sectional area larger than the flow path cross-sectional area of the first exhaust line 230, the first exhaust line 230 branching from the middle of the second exhaust line 231, capable of forming the film on the wafer 200 while performing exhaust through the first exhaust line 230, and capable of modifying the film while performing switching from the first exhaust line 230 to the second exhaust line 231 and performing exhaust by making the exhaust amount larger than that of the first exhaust line. As a result, even when the supply amount of the modifier containing the active species is increased, the low pressure can be maintained, and further, the processing pressure can be reduced. Such a low pressure can increase the transport efficiency of the activated modifier. Thus, since the active species (activated modifier) spreads over the entire wafer 200, the in-plane uniformity of film thickness can be improved.

In addition, according to one aspect of the present disclosure, the flow path cross-sectional area of the second exhaust line 231 is made to be twice or more the flow path cross-sectional area of the first exhaust line 230. As a result, since the exhaust amount of gas in the step of modifying the film can be made larger than the exhaust amount of gas in the step of forming the film on the wafer 200, the low pressure can be maintained even when the supply amount of the modifier is increased, and further, the processing pressure can be reduced. Such a low pressure can increase the transport efficiency of the activated modifier. Thus, since the active species (activated modifier) spreads over the entire wafer 200, the in-plane uniformity of film thickness can be improved.

In addition, according to one aspect of the present disclosure, switching can be performed from the first exhaust line 230 to the second exhaust line 231 after a film is formed on the wafer 200 and before the wafer is modified. Since the exhaust conductance can be lowered by switching from the first exhaust line 230 to the second exhaust line 231 as described above, the low pressure can be maintained while the modifier or the active species is increased. The low pressure is maintained as described above, whereby the transport efficiency of the modifier or the active species can be increased. Thus, since the active species (activated modifier) spreads over the entire wafer 200, the in-plane uniformity of film thickness can be improved.

In addition, according to one aspect of the present disclosure, switching can be performed from the first exhaust line 230 to the second exhaust line 231 while the process chamber 201 is purged after a film is formed on the wafer 200 and before the film is modified. Thus, by switching from the first exhaust line 230 to the second exhaust line 231, it is possible to lower the conductance, so that the low pressure can be maintained while the modifier or the active species is increased. The low pressure is maintained as described above, whereby the transport efficiency of the activated modifier or active species can be increased. Thus, since the active species (activated modifier) spreads over the entire wafer 200, the in-plane uniformity of film thickness can be improved.

In addition, according to one aspect of the present disclosure, the second exhaust line 231 is provided with the vacuum pump 236 (see FIG. 7) serving as an exhaust apparatus that exhausts the atmosphere of the process chamber 201. The controller 121 is configured to be capable of operating the vacuum pump 236 when modifying the film. The process chamber 201 is exhausted through the second exhaust line 231 by the vacuum pump 236 as described above, whereby the exhaust amount of gas in the modifying step increases, and the transport efficiency of the modifier or the active species can be increased. Thus, since the active species (activated modifier) spreads over the entire wafer 200, the in-plane uniformity of film thickness can be improved.

In addition, according to one aspect of the present disclosure, the controller 121 is configured to be capable of performing exhaust in both the first exhaust line 230 and the second exhaust line 231 when modifying the film. As a result, the process chamber 201 is exhausted through both the first exhaust line 230 and the second exhaust line 231, whereby the exhaust amount of gas in the modifying step increases, and the transport efficiency of the modifying agent or the active species can be increased. Thus, since the active species (activated modifier) spreads over the entire wafer 200, the in-plane uniformity of film thickness can be improved.

In addition, according to one aspect of the present disclosure, the activator that activates a reactant gas is provided, and a film can be formed on the wafer 200 by supply of the reactant gas activated by the activator. Specifically, the rod-shaped electrodes 269 and 270 and the electrode protection tube 275 are included, which are serving as the activator that activates an inert gas, and the film formed on the wafer 200 can be modified by supply of the inert gas activated by the rod-shaped electrodes 269 and 270 and the electrode protection tube 275, which are serving as the activator. As described above, since the film density and impurities in the film can be improved by use of the activated inert gas (modifier), a film having good film quality can be formed at a low temperature.

In addition, in such a configuration, since the exhaust amount of gas in the step of modifying the film can be made larger than the exhaust amount of gas in the step of forming the film on the wafer 200, the low pressure can be maintained even when the supply amount of the activated modifier is increased, and further, the processing pressure can be reduced. Such a low pressure can increase the transport efficiency of the activated modifier. Thus, since the active species (activated modifier) spreads over the entire wafer 200, the in-plane uniformity of film thickness can be improved.

Furthermore, according to one aspect of the present disclosure, in the modifying step, since the source gas and the reactant gas are not supplied, production of by-products is minor. This makes it possible to suppress adhesion of by-products to the vacuum pump 246 and to reduce the maintenance cost. In addition, even in the case of an exhaust apparatus serving as a type of a pump to which application is difficult from a viewpoint of adhesion of by-products in a normal process, application is possible.

Although the present disclosure has been described in detail with respect to specific embodiments, the present disclosure is not limited to such embodiments, and it is apparent to those skilled in the art that various other embodiments can be taken within the scope of the present disclosure. In addition, the above-described aspects and modified examples of the present disclosure can be appropriately combined and used.

In the above embodiments, the supply of the source gas has been described using the flash flow supply, but it is needless to say that the supply of the source gas is not limited to the flash flow supply and may be supplied by another supply method.

Although not particularly described in the above embodiments, as the source gas, sources may be used such as a silicon-based source, a titanium-based source (for example, titanium tetrachloride), a tantalum-based source (for example, tantalum pentachloride), a hafnium-based source (for example, tetrakis ethyl methyl amino hafnium), a zirconium-based source (for example, tetrakis ethyl methyl amino zirconium), or an aluminum-based source (trimethyl aluminum).

Although not particularly described in the above embodiments, the N₂ gas is used as the inert gas, but other gases may be used such as an Ar gas, a He gas, a Ne gas, and a Xe gas.

Although not particularly described in the above embodiments, the present disclosure may be used not only in a semiconductor manufacturing apparatus but also in an apparatus that processes a glass substrate such as an LCD apparatus.

Although not particularly described in the above embodiments, the film forming processing of the present disclosure may be used, for example, for CVD, PVD, processing of forming an oxide film, a nitride film, or both, processing of forming a film containing metal, and the like, and further, may be used for processing such as annealing, oxidizing, nitriding, or diffusion processing.

Although not particularly described in the above embodiments, for each component, the number of components is not limited to one, and a plurality of components may be present unless otherwise specified in the specification.

According to the present disclosure, the in-plane uniformity of film thickness of the substrate can be improved.

What is claimed is:

1. A method of processing a substrate, comprising:
a film forming step of forming a film on a substrate in a process chamber; and
a modifying step of modifying the film in the process chamber, wherein:
an exhaust amount discharged from the process chamber in the modifying step is made larger than an exhaust amount discharged from the process chamber in the film forming step.

2. The method of processing a substrate according to claim 1, wherein the film forming step further includes a source gas supply step of supplying a source gas to the substrate, and a reactant gas supply step of supplying a reactant gas to the substrate.

3. The method of processing a substrate according to claim 2, wherein:
the source gas supply step and the reactant gas supply step are repeated in this order,
a purge step of purging an inside of the process chamber is included during a transition from the source gas supply step to the reactant gas supply step or during a transition from the reactant gas supply step to the source gas supply step, and
the exhaust amount discharged from the process chamber in the modifying step is made larger than an exhaust amount discharged from the process chamber in the purge step.

4. The method of processing a substrate according to claim 2, further comprising:
a first purge step of purging an inside of the process chamber between the reactant gas supply step and the modifying step, wherein:
in the first purge step, the exhaust amount is increased from an exhaust amount discharged from the process chamber in the reactant gas supply step to the exhaust amount discharged from the process chamber in the modifying step.

5. The method of processing a substrate according to claim 1, wherein an active species in the modifying step is activated by heat.

6. The method of processing a substrate according to claim 1, wherein an active species in the modifying step is plasma-excited.

7. The method of processing a substrate according to claim 1, wherein the film forming step and the modifying step are set as one cycle and executed a predetermined number of times or more.

8. The method of processing a substrate according to claim 1, wherein the film forming step is executed a plurality of times, and then the modifying step is executed.

9. The method of processing a substrate according to claim 1, further comprising:
a second purge step of purging an inside of the process chamber between the film forming step and the modifying step, wherein:
in the second purge step, the exhaust amount is increased from the exhaust amount discharged from the process chamber in the film forming step to the exhaust amount discharged from the process chamber in the modifying step.

10. A method of processing a substrate accordingly to claim 1, further comprising manufacturing a semiconductor device.

11. A substrate processing apparatus comprising:
a first exhaust line configured to exhaust an atmosphere of a process chamber in which a substrate is processed;
a second exhaust line configured to have a flow path cross-sectional area larger than a flow path cross-sectional area of the first exhaust line, the first exhaust line branching from a middle of the second exhaust line; and
a controller configured to be capable of forming a film on the substrate while exhausting the atmosphere of the process chamber through the first exhaust line, and configured to be capable of modifying the film while performing switching from the first exhaust line to the second exhaust line and exhausting the atmosphere of the process chamber by making an exhaust amount larger than that when forming the film on the substrate.

12. The substrate processing apparatus according to claim 11, wherein the flow path cross-sectional area of the second exhaust line is made to be twice or more the flow path cross-sectional area of the first exhaust line.

13. The substrate processing apparatus according to claim 11, wherein the controller is configured to be capable of performing switching from the first exhaust line to the second exhaust line after forming the film on the substrate and before modifying the film.

14. The substrate processing apparatus according to claim 11, wherein the controller is configured to be capable of performing switching from the first exhaust line to the second exhaust line while purging the process chamber after forming the film on the substrate and before modifying the film.

15. The substrate processing apparatus according to claim 11, wherein:
the second exhaust line is further provided with an exhaust apparatus that evacuates the atmosphere of the process chamber, and
the controller is configured to be capable of operating the exhaust apparatus when modifying the film.

16. The substrate processing apparatus according to claim 11, wherein the controller is configured to be capable of performing exhaust in both the first exhaust line and the second exhaust line when modifying the film.

17. The substrate processing apparatus according to claim 11, further comprising:
a source gas line that supplies a source gas to the substrate, and a reactant gas line that supplies a reactant gas to the substrate, wherein:
the controller is configured to be capable of forming the film on the substrate by supplying the source gas alone or both the source gas and the reactant gas to the substrate.

18. The substrate processing apparatus according to claim 17, further comprising:
an activator that activates the reactant gas, wherein:
the substrate processing apparatus is configured to be capable of forming the film on the substrate by supplying the reactant gas activated by the activator.

19. The substrate processing apparatus according to claim 11, further comprising:
an activator that activates an inert gas, wherein:
the substrate processing apparatus is configured to be capable of modifying the film formed on the substrate by supplying the inert gas activated by the activator.

20. A non-transitory computer-readable recording medium recording a program executed in a substrate processing apparatus including:
a first exhaust line configured to exhaust an atmosphere of a process chamber in which a substrate is processed; and
a second exhaust line configured to have a flow path cross-section larger than a flow path cross-section of the first exhaust line, the first exhaust line branching from a middle of the second exhaust line,
the program causing the substrate processing apparatus to execute:
a procedure of forming a film on the substrate while performing exhaust through the first exhaust line; and
a procedure of modifying the film while performing switching from the first exhaust line to the second exhaust line, and performing exhaust by making an exhaust amount larger than that at time of the procedure of forming the film.
